(19) United States
(12) Patent Application Publication
(10) Pub. No.: US 2025/0318267 A1
(43) Pub. Date: Oct. 9, 2025

(54) BACKSIDE TO FRONTSIDE CONNECTION AMONG DIFFERENT METAL TRACKS

(71) Applicant: INTERNATIONAL BUSINESS MACHINES CORPORATION, ARMONK, NY (US)

(72) Inventors: Tsung-Sheng Kang, Ballston Lake, NY (US); Tao Li, Slingerlands, NY (US); Ruilong Xie, Niskayuna, NY (US); Julien Frougier, Albany, NY (US)

(21) Appl. No.: 18/630,008

(22) Filed: Apr. 9, 2024

(51) Int. Cl. H01L 27/12

(52) U.S. Cl. CPC H10D 86/60; H10D 86/0214; H10D 86/441

(57) ABSTRACT

Embodiments of present invention provide a semiconductor structure. The semiconductor structure includes a deep trench via in a single diffusion break region; a frontside metal wire conductively connected to a top surface of the deep trench via; and a backside metal wire conductively connected to a bottom surface of the deep trench via, where the frontside metal wire and the backside metal wire are parallel to each other and perpendicular to the deep trench via. A method of forming the same is also provided.

### BACKGROUND

The present application relates to manufacturing of semiconductor integrated circuits. More particularly, it relates to method of forming backside to frontside connection between different metal tracks, and the structure formed thereby.

As semiconductor industry moves towards smaller node, field-effect-transistors (FETs) are aggressively scaled to fit into reduced footprint or real estate, which is often dictated by the node size, with increased device density. As one of the approaches, backside power distribution network (BSPDN) is introduced as a mean to further enhance the device density.

With a semiconductor chip having multiple frontside metal tracks of a frontside back-end-of-line (BEOL) structure and multiple backside metal tracks of a backside BEOL (BBEOL) structure, there is often the necessity for communication between different metal tracks at the frontside and at the backside. For example, a metal level 1 (M1) at the frontside may need to communicate with a backside metal level 1 (BM1) at the backside. When the M1 at the frontside is vertically aligned with the BM1 at the backside, such communication may be enabled by a deep vertical via formed between the two metal levels. However, metal levels at the frontside and at the backside are not always vertically aligned and, in reality, they may sometimes be misaligned due to various reasons. Under such circumstances, a deep vertical via may not be able to connect the frontside metal level with the backside metal level for communication.

### SUMMARY

Embodiments of present invention provide a semiconductor structure. The semiconductor structure includes a deep trench via in a single diffusion break region; a frontside metal wire conductively connected to a top surface of the deep trench via; and a backside metal wire conductively connected to a bottom surface of the deep trench via, where the frontside metal wire and the backside metal wire are parallel to each other and perpendicular to the deep trench via. The deep trench via enables communication between the frontside metal wire and the backside metal wire.

According to one embodiment, the semiconductor structure further includes a metal gate and a gate cut dielectric, where the deep trench via is in a width direction of the metal gate and the gate cut dielectric insulates the deep trench via from the metal gate.

According to another embodiment, the semiconductor structure further includes a first set of inner spacers directly contacting a first side of the deep trench via and a second set of inner spacers directly contacting a second side of the deep trench via, the first side of the deep trench via being opposite the second side of the deep trench via.

According to yet another embodiment, the semiconductor structure further includes a first source/drain (S/D) region of a first nanosheet (NS) transistor and a second S/D region of a second NS transistor, where the first S/D region directly contacts the first set of inner spacers and the second S/D region directly contacts the second set of inner spacers.

According to one embodiment, the semiconductor structure further includes a frontside via, a backside via, and a backside contact, where the frontside metal wire is conductively connected to the top surface of the deep trench via through the frontside via, and the backside metal wire is conductively connected to the bottom surface of the deep trench via through the backside via and the backside contact.

In one embodiment, the backside contact is directly adjacent to a shallow-trench-insulation (STI), the STI being directly underneath the deep trench via and embedded in a substrate.

In another embodiment, the frontside metal wire is not vertically aligned with the backside metal wire and a horizontal distance between the frontside metal wire and the backside metal wire is less than a length of the deep trench via.

Embodiments of present invention further provide a method of forming a semiconductor structure. The method includes forming a first sacrificial gate of a first nanosheet (NS) transistor, a second sacrificial gate of a second NS transistor, and a third sacrificial gate on a substrate; forming a first source/drain (S/D) region of the first NS transistor between the first sacrificial gate and the third sacrificial gate; forming a second S/D region of the second NS transistor between the second sacrificial gate and the third sacrificial gate; forming a backside contact in the substrate underneath a single diffusion break region; forming a deep trench via in the single diffusion break region directly above the backside contact, the single diffusion break region being between the first S/D region of the first NS transistor and the second S/D region of the second NS transistor; forming a frontside metal wire conductively connected to a top surface of the deep trench via; and forming a backside metal wire conductively connected to a bottom surface of the deep trench via.

According to one embodiment, the method further includes forming a frontside via directly contacting the top surface of the deep trench via, wherein the frontside metal wire directly contacts the frontside via.

According to another embodiment, the method further includes forming a backside via directly contacting the backside contact, wherein the backside metal wire directly contacts the backside via.

According to yet another embodiment, the method further includes forming a first set of inner spacers between the first S/D region of the first NS transistor and a first side of the deep trench via; and forming a second set of inner spacers between the second S/D region of the second NS transistor and a second side of the deep trench via, where the first side of the deep trench via is opposite the second side of the deep trench via.

In one embodiment, forming the backside contact includes selectively removing the third sacrificial gate and one or more nanosheets exposed by the removal of the third sacrificial gate to create a first opening between the first S/D region of the first NS transistor and the second S/D region of the second NS transistor, the first opening exposing the substrate; recessing a portion of the substrate to create a second opening in the substrate; and filling the second opening with a conductive material to form the backside contact.

In another embodiment, forming the deep trench via includes filling the first opening between the first S/D region and the second S/D region, in the single diffusion region, with the conductive material to form the deep trench via.

In yet another embodiment, forming the frontside metal wire includes forming the frontside metal wire in a first direction perpendicular to the deep trench via; and forming the backside metal wire includes forming the backside metal wire, from a backside of the substrate, in a second direction perpendicular to the deep trench via and parallel to the first direction, where the backside metal wire is not vertically aligned with the frontside metal wire.

According to one embodiment, the method further includes forming a gate cut dielectric insulating a metal gate from the deep trench via, where the deep trench via is in a width direction of the metal gate.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B to FIGS. 13A and 13B are demonstrative illustrations of cross-sectional views and FIG. 1C to FIG. 13C are simplified top views of a semiconductor structure at various steps of manufacturing thereof according to embodiments of present invention; and

FIG. 14 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

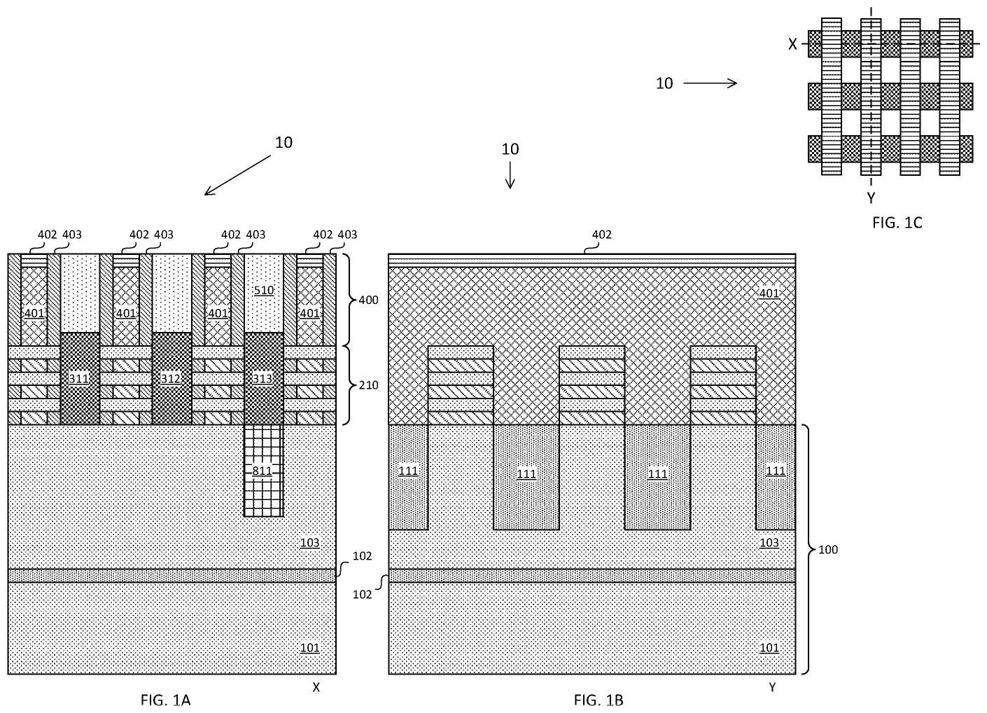

FIGS. 1A and 1B are demonstrative illustrations of different cross-sectional views and FIG. 1C is a simplified top view of a semiconductor structure in a step of manufacturing thereof according to one embodiment of present invention. More specifically, FIG. 1A illustrates a cross-sectional view of the semiconductor structure along a dashed line X as illustrated in FIG. 1C. In other words, the cross-sectional view in FIG. 1A is made across the gate in a direction along the length of the gate. FIG. 1B illustrates a cross-sectional view of the semiconductor structure along a dashed line Y as illustrated in FIG. 1C. In other words, the cross-sectional view in FIG. 1B is made across the gate in a direction along the width of the gate. As its purpose is to show locations of the cross-sections illustrated in FIGS. 1A and 1B, FIG. 1C only selectively illustrates key elements such as, for example, nanosheets, gates, S/D regions, and elements that are formed or yet to be formed and whose views may be covered or exposed. Other elements such as dielectric cap layer, sidewall spacers, etc. may not necessarily be illustrated in order not to overcrowd FIG. 1C, and to the extent that their omission from FIG. 1C does not hinder the description of embodiments of present invention, which are mainly provided hereinafter with reference to FIGS. 1A and 1B.

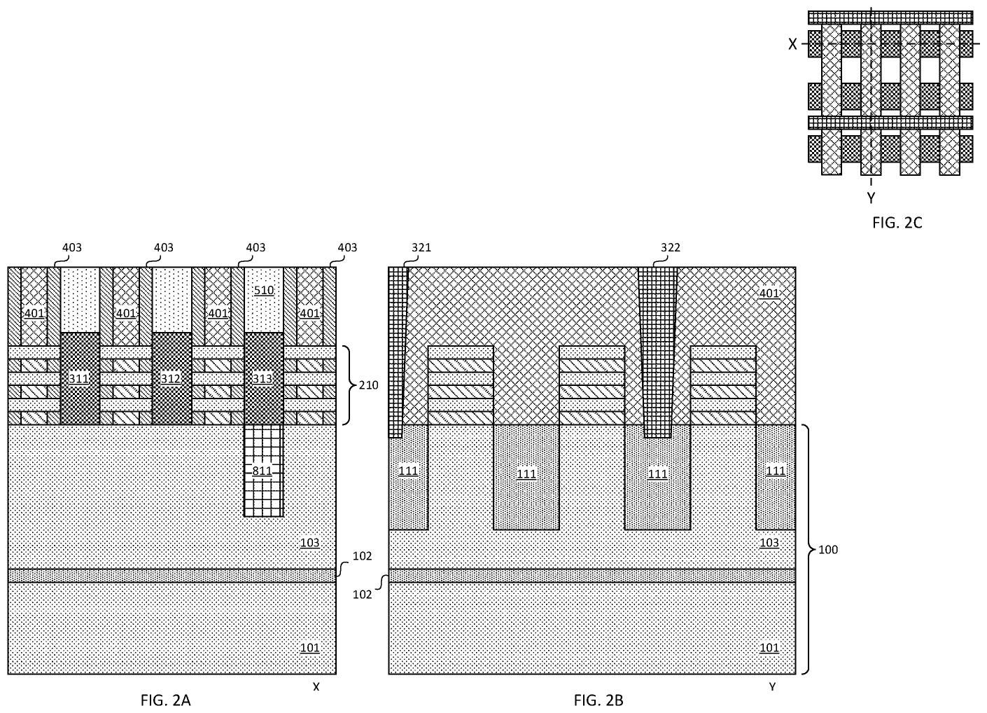

Likewise, FIGS. 2A and 2B to FIGS. 13A and 13B are demonstrative cross-sectional views and FIG. 2C to FIG. 13C are simplified top views of the semiconductor structure, at different manufacturing steps, illustrated in manners similar to FIGS. 1A, 1B, and 1C respectively.

Referring back to FIGS. 1A, 1B, and 1C, embodiments of present invention provide forming a semiconductor structure 10 that is demonstratively illustrated to include multiple sets of nanosheets 210 on top of a semiconductor substrate 100. The semiconductor substrate 100 may include a bulky silicon (Si) substrate 101, an etch-stop layer 102 on top of the Si substrate 101, and a Si layer 103 on top of the etch-stop layer 102. The etch-stop layer 102 may be a layer of dielectric material such as silicon-oxide (SiO₂) or silicon-nitride (SiN), or a layer of silicon-germanium (SiGe) having a material composition that is different from the Si substrate 101 that may enable a selective etch process based on material etch selectivity. One or more placeholders may be formed in the Si layer 103 such as, for example, a placeholder 811. The placeholder 811 may be made of a material, for example dielectric, that is different from the Si layer 103 such that it may be selectively removed later in a selective etch process. One or more shallow-trench-isolations (STIs) 111 may also be formed to be embedded in the Si layer 103.

The semiconductor structure 10 may also include multiple sacrificial gate structures 400 on top of and covering the multiple sets of nanosheets 210. The sacrificial gate structures 400 may each include a sacrificial gate 401 with a gate mask 402 on top thereof. Sidewall spacers 403 may be formed at sidewalls of the sacrificial gate 401. The semiconductor structure 10 may also include multiple source/drain (S/D) regions such as a first S/D region 311, a second S/D region 312, and a third S/D region 313 formed between and at end surfaces of the multiple sets of nanosheets 210. The multiple S/D regions are covered by a dielectric layer 510. The dielectric layer 510 fills spaces between the multiple sacrificial gate structures 400.

FIGS. 2A and 2B are demonstrative illustrations of different cross-sectional views and FIG. 2C is a simplified top view of a semiconductor structure in a step of manufacturing thereof, according to one embodiment of present invention. More particularly, following the step illustrated in FIGS. 1A, 1B, and 1C, embodiments of present invention provide performing a gate cut of the multiple sacrificial gates 401. In doing so, the gate mask 402 may first be optionally removed through, for example, a chemical-mechanical-polishing (CMP) process. Next, one or more deep trench openings may be created across the multiple sacrificial gates 401 in a direction perpendicular to a width direction and parallel to a length direction of the multiple sacrificial gates 401. The one or more deep trench openings may be made in areas that are vertically away from the multiple sets of nanosheets 210 and may expose one or more of the STIs 111 in the Si layer 103. Next, embodiments of present invention provide filling the one or more deep trench openings with a dielectric material such as, for example, SiN, SiO₂, or other suitable materials to form one or more gate cut dielectrics such as a first gate cut dielectric 321 and a second gate cut dielectric 322.

After forming the first and the second gate cut dielectric 321 and 322, a chemical-mechanical-polishing (CMP) process may be applied to planarize a top surface of the semiconductor structure 10. The CMP process may also remove the gate masks 402, if the gate masks 402 were not previously removed, thereby exposing at least the multiple sacrificial gates 401 underneath thereof for further processing.

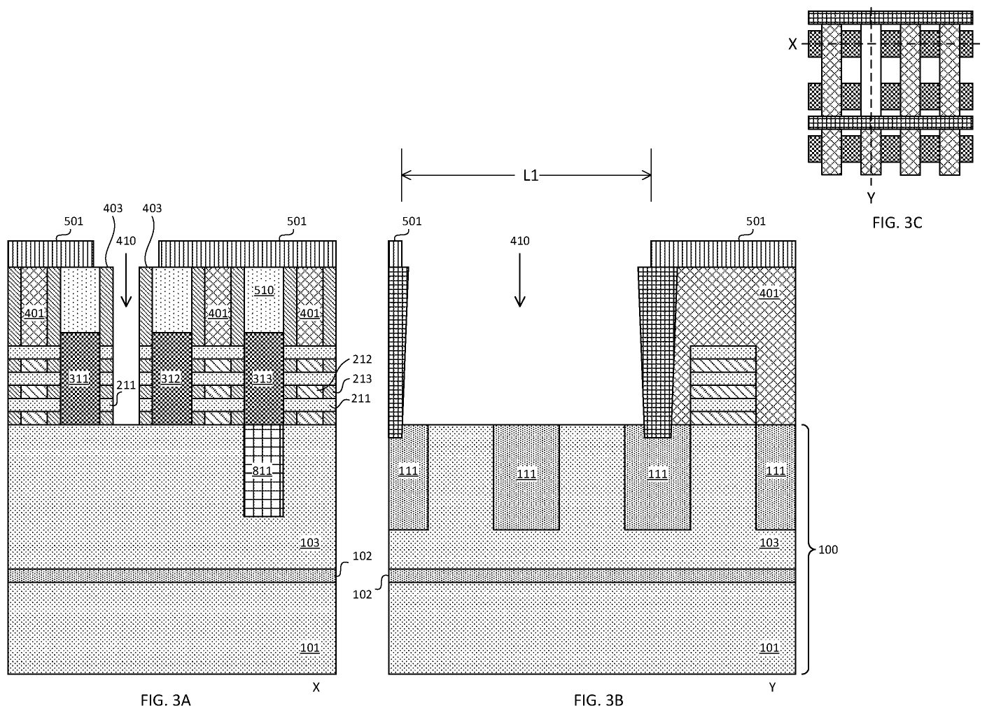

FIGS. 3A and 3B are demonstrative illustrations of different cross-sectional views and FIG. 3C is a simplified top view of a semiconductor structure in a step of manufacturing thereof, according to one embodiment of present invention. More particularly, following the step illustrated in FIGS. 2A, 2B, and 2C, embodiments of present invention provide processing a single diffusion break region between two S/D regions such as between the first S/D region 311 and the second S/D region 312. For example, embodiments of present invention provide forming a hard mask 501 on top of the semiconductor structure 10. The hard mask 501 may be, for example, an organic planarization (OPL) layer and may be patterned to have an opening exposing one of the sacrificial gates 401 that is between the first S/D region 311 and the second S/D region 312 in a region between the first gate cut dielectric 321 and the second gate cut dielectric 322. For example, the exposed sacrificial gate 401 may expand two or more sets of nanosheets 210 and have a length L1, ranging from about 100 nm to about 400 nm, along a width direction of the sacrificial gate 401 (see FIG. 3B). The exposed sacrificial gate 401 is then selectively removed through, for example, a selective etch process such as a reactive-ion-etch (RIE) process. The removal of the exposed sacrificial gate 401 reveals or exposes the two or more sets of nanosheets 210 underneath thereof.

As is demonstratively illustrated in FIG. 3A, each of the multiple sets of nanosheets 210 may include one or more nanosheets 211. The one or more nanosheets 211 may be separated from each other by one or more sacrificial sheets 212 and one or more sidewall spacers 213 there-in-between. The sidewall spacers 213 may also be referred to as inner spacers. Next, the exposed portions of the one or more nanosheets 211, for example between the first and the second S/D region 311 and 312 and more particularly between the two sidewall spacers 403, may be removed through one or more selective etch processes. The removal process may also remove the one or more sacrificial sheets 212 there-in-between, thereby creating an opening 410 that exposes end surfaces of remaining portions of the one or more nanosheets 211. The opening 410 also exposes a top surface of the Si layer 103 and one or more STIs 111 embedded therein. Here, it is to be noted that in some embodiment the removal process may not remove completely the bottom-most sacrificial sheet 212, resulting in a small portion of that sacrificial sheet 212 remaining on top of the Si layer 103.

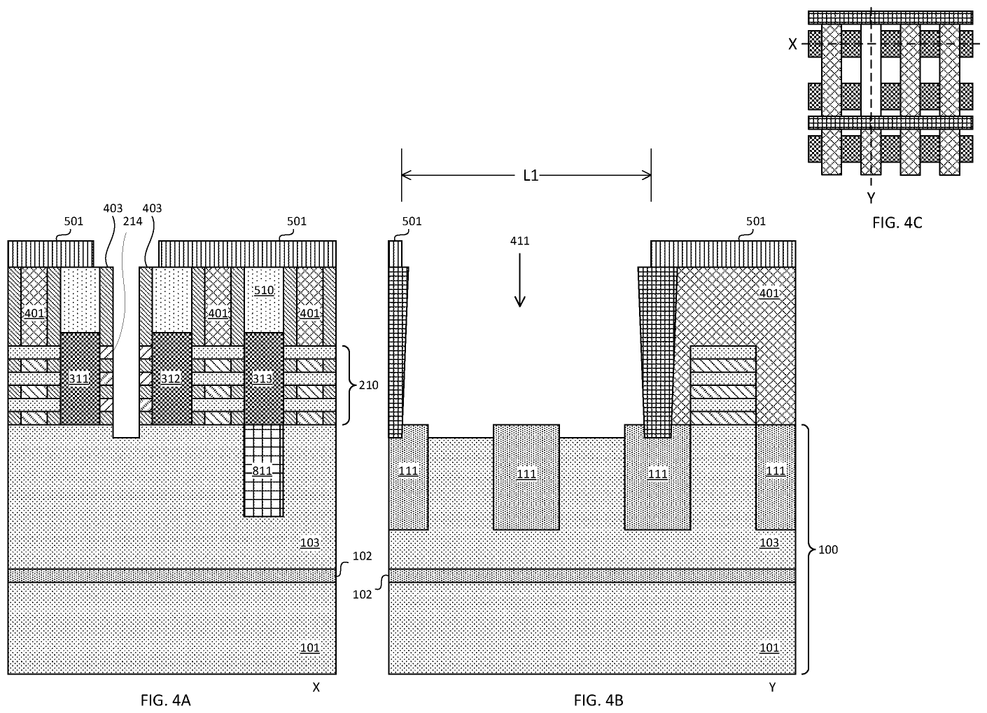

FIGS. 4A and 4B are demonstrative illustrations of different cross-sectional views and FIG. 4C is a simplified top view of a semiconductor structure in a step of manufacturing thereof, according to one embodiment of present invention. More particularly, following the step illustrated in FIGS. 3A, 3B, and 3C, embodiments of present invention provide recessing or removing the remaining portions of the one or more nanosheets 211, underneath and covered by the sidewall spacers 403, to create one or more recesses or indentations. Next, the one or more recesses or indentations may be filled with a dielectric material to form one or more inner spacers 214. The one or more inner spacers 214 may be formed through, for example, an atomic-layer-deposition (ALD) process, a chemical-vapor-deposition (CVD) process, or a physical-vapor-deposition (PVD) process. Together with the one or more sidewall spacers 213, which are inner spacers as well, the one or more inner spacers 214 may insulate the first S/D region 311 and the second S/D region 312 from a deep trench via to be formed in the opening 410, which is conventionally used for forming a single diffusion break.

While removing the remaining portions of the one or more nanosheets 211 in the process of forming the one or more inner spacers 214, in one embodiment the exposed Si layer 103 may be further recessed as well, resulting in a deepened opening 411.

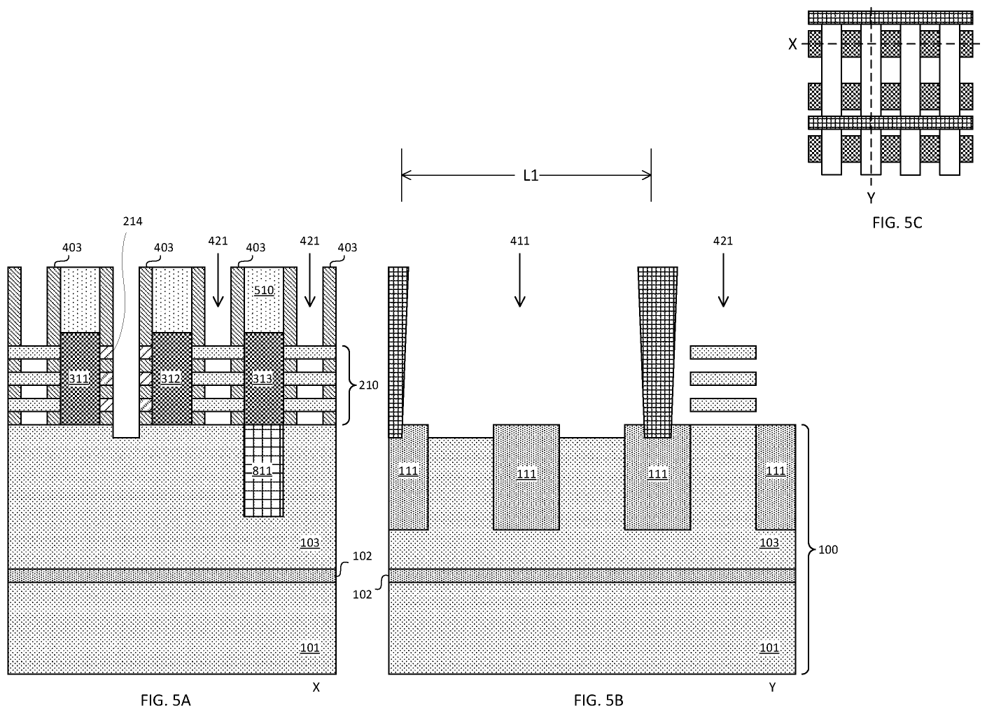

FIGS. 5A and 5B are demonstrative illustrations of different cross-sectional views and FIG. 5C is a simplified top view of a semiconductor structure in a step of manufacturing thereof, according to one embodiment of present invention. More particularly, following the step illustrated in FIGS. 4A, 4B, and 4C, embodiments of present invention provide removing the hard mask 501 to expose the one or more remaining sacrificial gates 401. Next, embodiments of present invention provide performing a replacement-metal-gate (RMG) process to form one or more metal gates of one or more nanosheet transistors. In doing so, a selective etch process may first be applied to remove the one or more remaining sacrificial gates 401 between the sidewall spacers 403; and remove the sacrificial sheets 212 between the nanosheets 211 of the multiple sets of nanosheets 210 underneath the sacrificial gates 401. The removal of the sacrificial gates 401 and the sacrificial sheets 212 creates one or more openings 421 that expose portions of the one or more nanosheets 211 in a region between the sidewall spacers 403 and between the sidewall spacers 213.

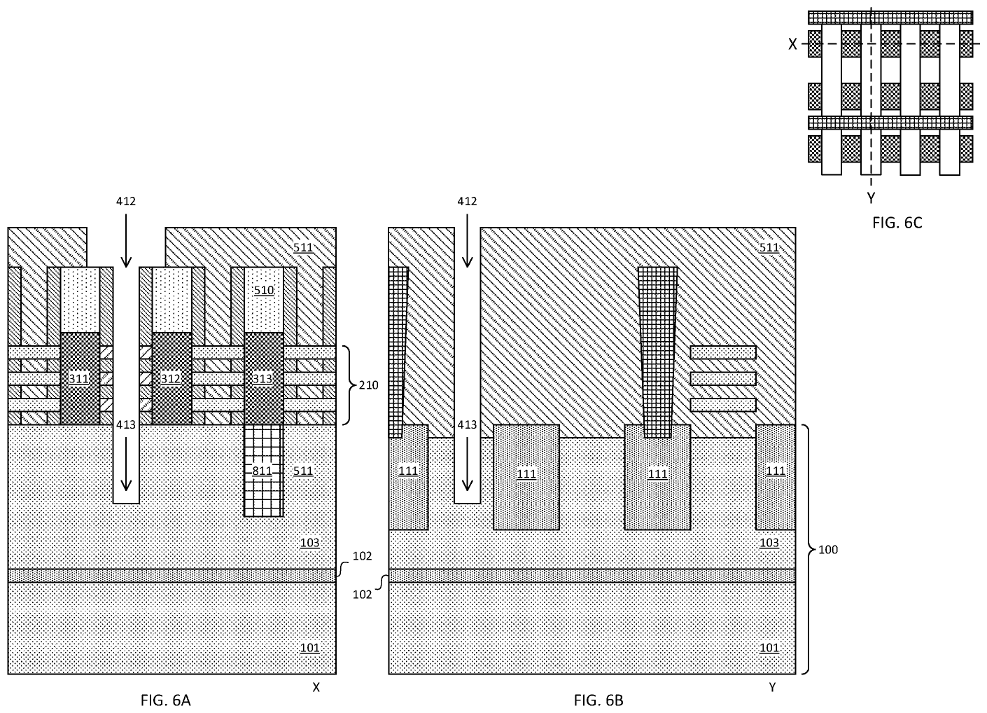

FIGS. 6A and 6B are demonstrative illustrations of different cross-sectional views and FIG. 6C is a simplified top view of a semiconductor structure in a step of manufacturing thereof, according to one embodiment of present invention. More particularly, following the step illustrated in FIGS. 5A, 5B, and 5C, embodiments of present invention provide forming a hard mask 511 by depositing an OPL layer and patterning the OPL layer to have an opening 412. The opening 412 may be substantially aligned with the opening 411, along the gate length direction as is illustrated in FIG. 6A, between the first S/D region 311 and the second S/D region 312. In the gate width direction, the opening 412 may be substantially narrower than the opening 411 as is illustrated in FIG. 6B. The opening 412 may represent a pattern of a backside contact. The opening 412 may be on top of the Si layer 103 away from any STIs 111, on top of the Si layer 103 but adjacent to one of the STIs 111, or partially on top of the Si layer 103 and cover a portion of one of the STIs 111. In the meantime, the hard mask 511 may cover the exposed one or more nanosheets 211 in the one or more openings 421, thereby protect the one or more nanosheets 211.

After forming the hard mask 511, the portion of the Si layer 103 exposed by the opening 412 may be recessed to create an opening 413 in the Si layer 103. In one embodiment, as is illustrated in FIG. 6B, the opening 413 may be between two STIs 111 and fully embedded in the Si layer 103. In another embodiment, the opening 413 may be immediately next to or adjacent to one of the STIs 111, not shown here though, exposing a portion of a sidewall and a top surface of the STI 111. In any case, the opening 413 may be created for forming a backside contact as being described below in more detail.

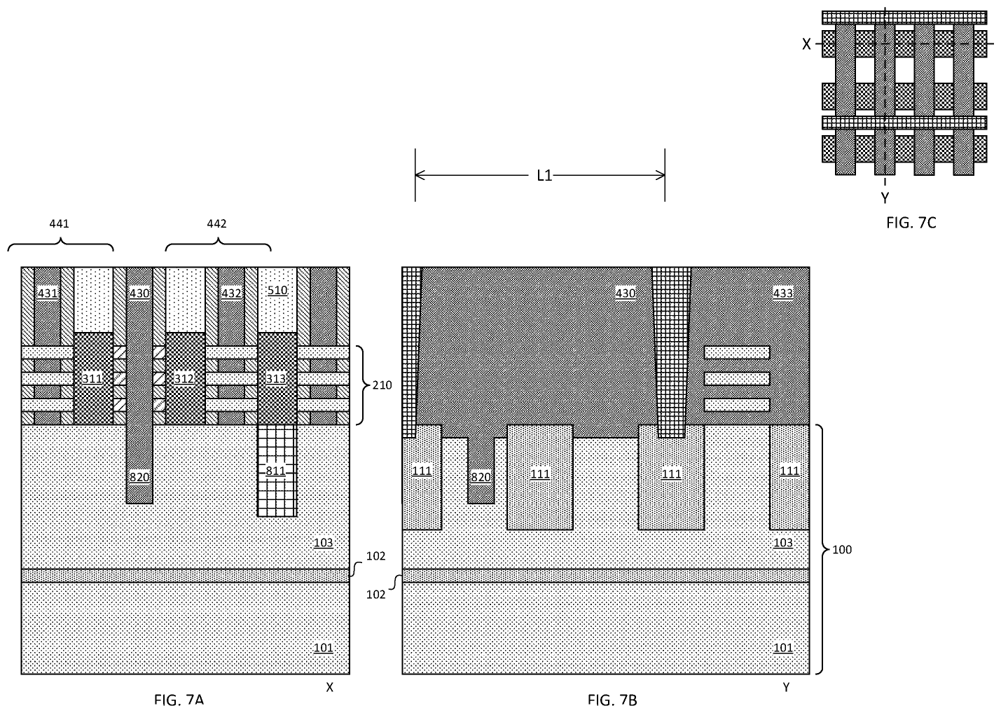

FIGS. 7A and 7B are demonstrative illustrations of different cross-sectional views and FIG. 7C is a simplified top view of a semiconductor structure in a step of manufacturing thereof, according to one embodiment of present invention. More particularly, following the step illustrated in FIGS. 6A, 6B, and 6C, embodiments of present invention provide forming metal gates of one or more nanosheet transistors in a replacement-metal-gate (RMG) process. For example, embodiments of present invention provide removing the hard mask 511 to expose or re-expose the opening 413 for forming a backside contact; expose or re-expose the opening 411 for forming a deep trench via; and expose or re-expose the central portion of the one or more nanosheets 211, of the one or more sets of nanosheets 210 between the sidewall spacers 403, for forming one or more metal gates. Next, a backside contact 820 may be formed in the opening 413 and a deep trench via 430 of local interconnect (LI) may be formed in the opening 411. Concurrently or separately, one or more metal gates such as a first metal gate 431 of a first nanosheet transistor 441, a second metal gate 432 of a second nanosheet transistor 442, and a third metal gate 433 of a third nanosheet transistor may be formed. More particularly, the one or more metal gates 431, 432, and 433 may be formed by depositing or forming a gate dielectric layer covering the exposed portions of the one or more nanosheets 211; depositing or forming one or more work-function metal layers on top of the gate dielectric layer; and depositing or forming one or more gate metals on top of the work-function metal layers. On the other hand, the backside contact 820 and the deep trench via 430 may be formed by depositing the one or more gate metals in the openings 413 and 411.

As is demonstratively illustrated in FIG. 7A, the first nanosheet transistor 441 may be adjacent to a left side of the deep trench via 430, via the sidewall spacer 403; the second nanosheet transistor 442 may be adjacent to a right side of the deep trench via 430, via another sidewall spacer 403; while the deep trench via 430 is formed in a single diffusion break region. On the other hand, the third metal gate 433 is formed to be insulated from the deep trench via 430 by the second gate cut dielectric 322.

The backside contact 820 and the deep trench via 430 may be formed with a conductive material such as, for example, tungsten (W), cobalt (Co), ruthenium (Ru), copper (Cu), aluminum (Al), or other suitable materials to serve as a local interconnect. In one embodiment, the backside contact 820 may be between two STIs 111. In another embodiment, the backside contact 820 may be formed directly next to or adjacent to one of the STIs 111. In other words, the backside contact 820 may be formed to be self-aligned to one of the STIs 111.

The deep trench via 430 may be formed in a single diffusion break region between the first and the second nanosheet transistors 441 and 442; and have a length L1 in a direction along the width of the metal gates, as is demonstratively illustrated in FIG. 7B. In addition to being insulated from the first S/D region 311 and the second S/D region 312 widthwise, the deep trench via 430 is lengthwise insulated from other metal gates, such as insulated from the third metal gate 433, by the one or more gate cut dielectrics such as the second gate cut dielectric 322.

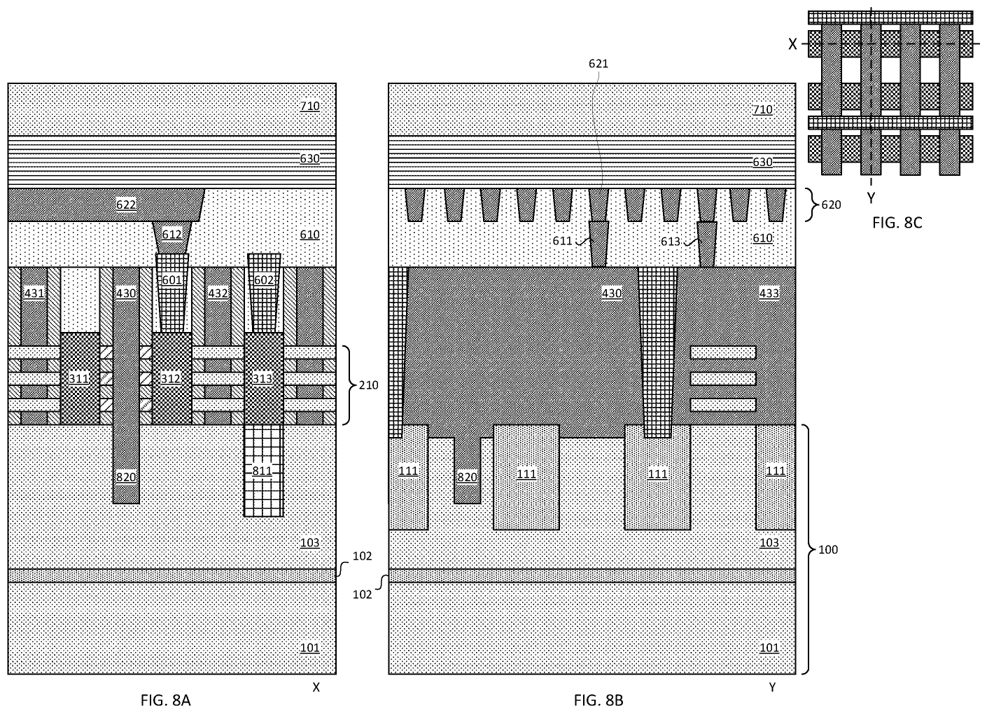

FIGS. 8A and 8B are demonstrative illustrations of different cross-sectional views and FIG. 8C is a simplified top view of a semiconductor structure in a step of manufacturing thereof, according to one embodiment of present invention. More particularly, following the step illustrated in FIGS. 7A, 7B, and 7C, embodiments of present invention provide forming additional dielectric layer such as a dielectric layer 610 on top of the semiconductor structure 10, in particular on top of the dielectric layer 510, the deep trench via 430, and the one or more metal gates 431, 432, and 433; forming one or more frontside S/D contacts such as a first frontside S/D contact 601 and a second frontside S/D contact 602; and forming one or more frontside vias such as a first frontside via 611 in direct contact with a top surface of the deep trench via 430 of local interconnect, a second frontside via 612 in contact with the first frontside S/D contact 601; and a third frontside via 613 in contact with the third metal gate 433.

Embodiments of present invention further provide forming a frontside metal level such as a frontside metal level 620 on top of the dielectric layer 610. The frontside metal level 620 may include a plurality of metal tracks such as a plurality of metal wires, including a first frontside metal wire 621 and a second frontside metal wire 622, orientated in a first direction perpendicular to or orthogonal to the length direction of the deep trench via 430. The first frontside metal wire 621 may be conductively connected to the top surface of the deep trench via 430 through the first frontside via 611.

Embodiments of present invention provide forming additional metal levels or back-end-of-line (BEOL) structure 630 on top of the frontside metal level 620. Next, a handling wafer 710 may be attached, such as through bonding, to the BEOL structure 630 such that the semiconductor structure 10 may be flipped upside-down for further processing from a backside of the semiconductor substrate 100.

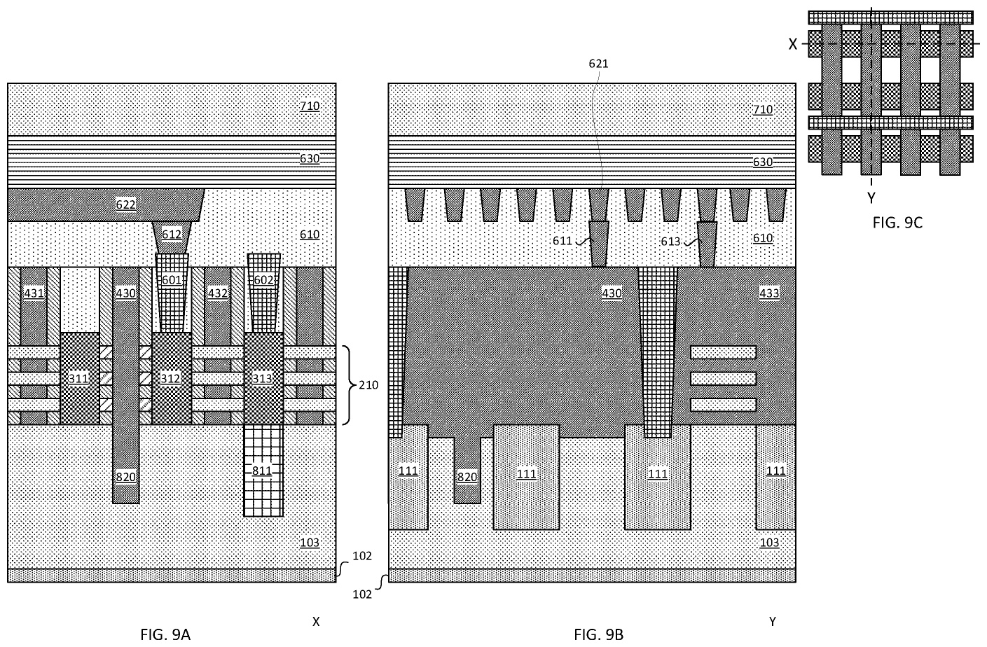

FIGS. 9A and 9B are demonstrative illustrations of different cross-sectional views and FIG. 9C is a simplified top view of a semiconductor structure in a step of manufacturing thereof, according to one embodiment of present invention. More particularly, following the step illustrated in FIGS. 8A, 8B, and 8C, embodiments of present invention provide selectively removing the bulky Si substrate 101 from the backside of the semiconductor substrate 100. The removal may be made through a grinding process, a wet or dry etch process, and/or a CMP process until the etch-stop layer 102 is exposed.

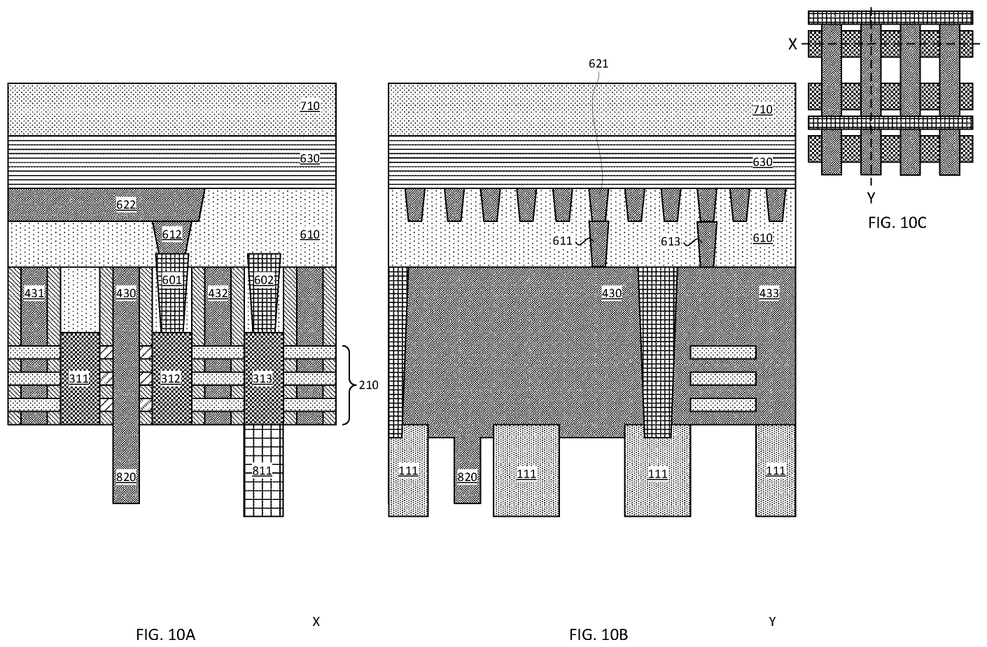

FIGS. 10A and 10B are demonstrative illustrations of different cross-sectional views and FIG. 10C is a simplified top view of a semiconductor structure in a step of manufacturing thereof, according to one embodiment of present invention. More particularly, following the step illustrated in FIGS. 9A, 9B, and 9C, embodiments of present invention provide removing the etch-stop layer 102 through a selective etch process to expose the Si layer 103, and selectively removing the Si layer 103. The removal of the Si layer 103 exposes the embedded one or more STIs 111; the one or more placeholders such as the placeholder 811; and the backside contact 820.

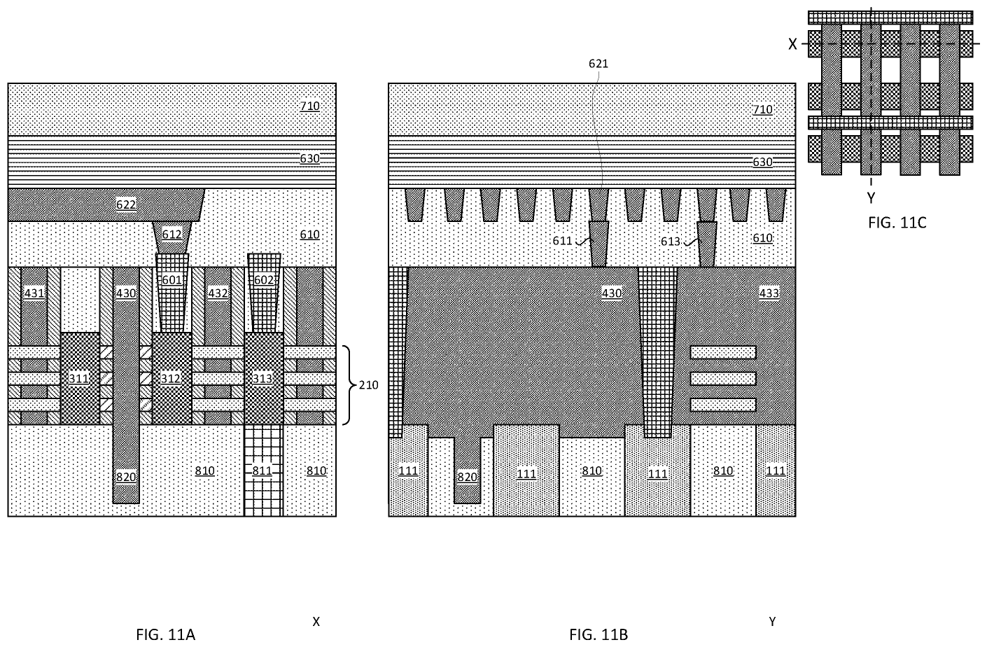

FIGS. 11A and 11B are demonstrative illustrations of different cross-sectional views and FIG. 11C is a simplified top view of a semiconductor structure in a step of manufacturing thereof, according to one embodiment of present invention. More particularly, following the step illustrated in FIGS. 10A, 10B, and 10C, embodiments of present invention provide depositing a dielectric material to form a dielectric layer 810 replacing the removed Si layer 103, and subsequently applying a CMP process to planarize a top surface of the dielectric layer 810 until the placeholder 811 is exposed.

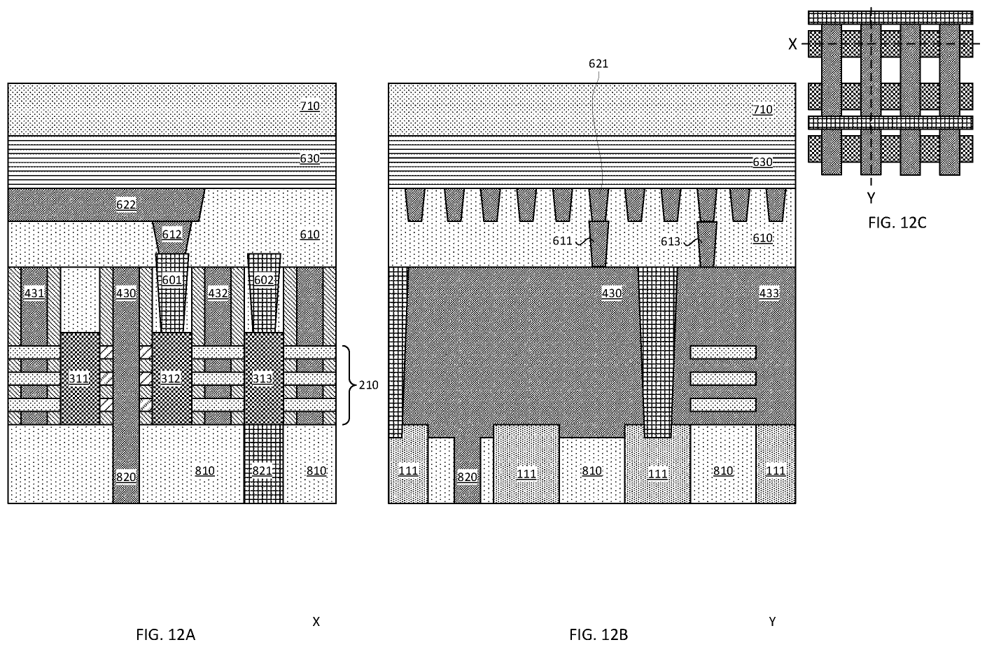

FIGS. 12A and 12B are demonstrative illustrations of different cross-sectional views and FIG. 12C is a simplified top view of a semiconductor structure in a step of manufacturing thereof, according to one embodiment of present invention. More particularly, following the step illustrated in FIGS. 11A, 11B, and 11C, embodiments of present invention provide removing the placeholder 811, in a selective etch process, to create an opening exposing a bottom surface of the third S/D region 313; filling the opening with a conductive material such as W, Co, Ru, Cu, Al, or other suitable materials, thereby forming a backside S/D contact 821. Next, a CMP process may be applied to recess the dielectric layer 810 until the backside contact 820 is exposed.

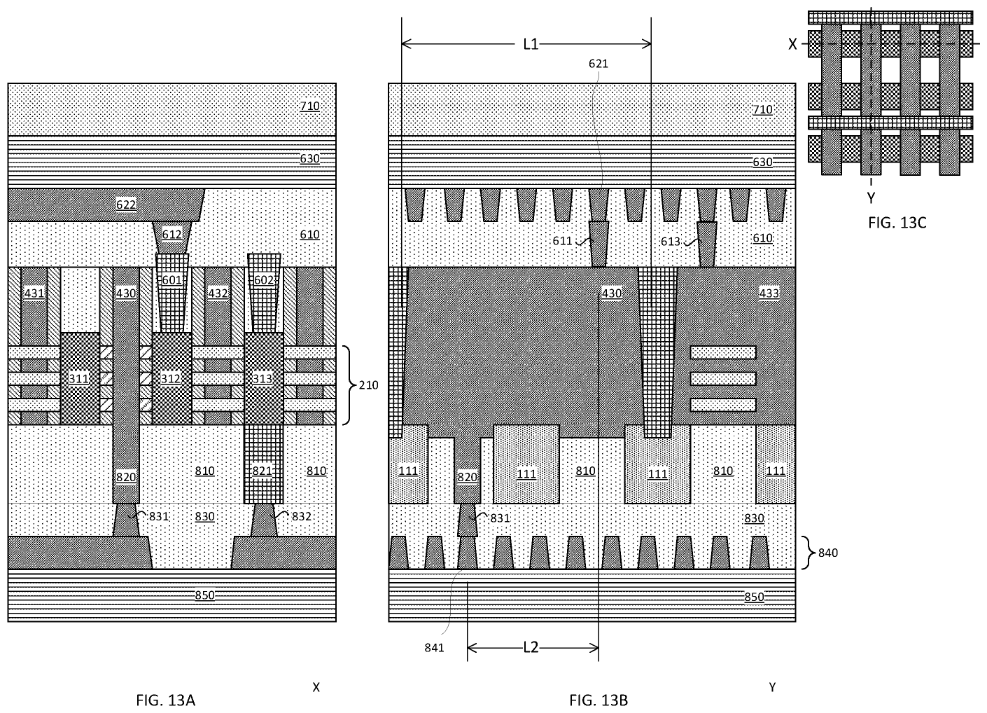

FIGS. 13A and 13B are demonstrative illustrations of different cross-sectional views and FIG. 13C is a simplified top view of a semiconductor structure in a step of manufacturing thereof, according to one embodiment of present invention. More particularly, following the step illustrated in FIGS. 12A, 12B, and 12C, embodiments of present invention provide forming a dielectric layer 830 on top of the backside S/D contact 821, the backside contact 820 and the dielectric layer 810; forming one or more backside vias such as a first backside via 831 and a second backside via 832. The first backside via 831 is in direct contact with the backside contact 820 and the second backside via 832 is in direct contact with the backside S/D contact 821.

Embodiments of present invention further provide forming a backside metal level such as a backside metal level 840 on top of the dielectric layer 830. The backside metal level 840 may include a plurality of metal tracks such as a plurality of metal wires, including a first backside metal wire 841, orientated in a second direction perpendicular to or orthogonal to the length direction of the deep trench via 430. In other words, the first frontside metal wire 621 and the first backside metal wire 841 may be parallel to each other. In one embodiment, the first frontside metal wire 621 is not vertically aligned with the first backside metal wire 841, and a horizontal distance L2 between the first frontside metal wire 621 and the first backside metal wire 841 may be less than the length L1 of the deep trench via 430.

Embodiments of present invention further provide forming additional backside metal levels or backside BEOL (BBEOL) structure 850 on top of the backside metal level 840, thereby forming the semiconductor structure 10.

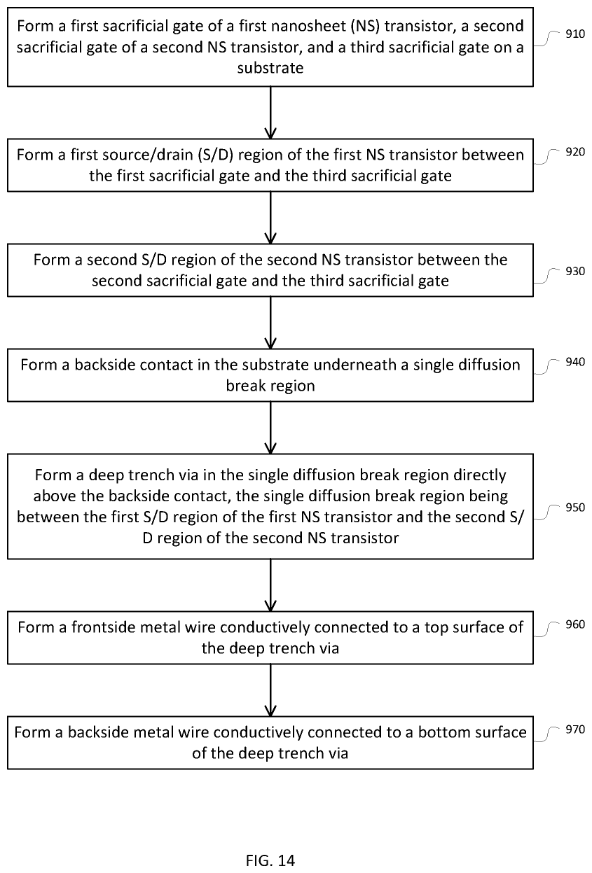

FIG. 14 is a demonstrative illustration of a flow-chart of a method of manufacturing a semiconductor structure according to embodiments of present invention. The method includes (910) forming a first sacrificial gate of a first nanosheet (NS) transistor, a second sacrificial gate of a second NS transistor, and a third sacrificial gate on a substrate; (920) forming a first source/drain (S/D) region of the first NS transistor between the first sacrificial gate and the third sacrificial gate; (930) forming a second S/D region of the second NS transistor between the second sacrificial gate and the third sacrificial gate; (940) forming a backside contact in the substrate underneath a single diffusion break region; (950) forming a deep trench via in the single diffusion break region directly above the backside contact, the single diffusion break region being between the first S/D region of the first NS transistor and the second S/D region of the second NS transistor; (960) forming a frontside metal wire conductively connected to a top surface of the deep trench via; and (970) forming a backside metal wire conductively connected to a bottom surface of the deep trench via.

Various examples may possibly be described by one or more of the following features in the following numbered clauses:

Clause 1: A semiconductor structure comprising a deep trench via in a single diffusion break region; a frontside metal wire conductively connected to a top surface of the deep trench via; and a backside metal wire conductively connected to a bottom surface of the deep trench via, wherein the frontside metal wire and the backside metal wire are parallel to each other and perpendicular to the deep trench via.

Clause 2: The semiconductor structure of clause 1, further comprising a metal gate and a gate cut dielectric, wherein the deep trench via is in a width direction of the metal gate and the gate cut dielectric insulates the deep trench via from the metal gate.

Clause 3: The semiconductor structure of clause 1, further comprising a first set of inner spacers directly contacting a first side of the deep trench via and a second set of inner spacers directly contacting a second side of the deep trench via, the first side of the deep trench via being opposite the second side of the deep trench via.

Clause 4: The semiconductor structure of clause 3, further comprising a first source/drain (S/D) region of a first nanosheet (NS) transistor and a second S/D region of a second NS transistor, wherein the first S/D region directly contacts the first set of inner spacers and the second S/D region directly contacts the second set of inner spacers.

Clause 5: The semiconductor structure of clause 1, further comprising a frontside via, a backside via, and a backside contact, wherein the frontside metal wire is conductively connected to the top surface of the deep trench via through the frontside via, and the backside metal wire is conductively connected to the bottom surface of the deep trench via through the backside via and the backside contact.

Clause 6: The semiconductor structure of clause 5, wherein the backside contact is directly adjacent to a shallow-trench-insulation (STI), the STI being directly underneath the deep trench via and embedded in a substrate.

Clause 7: The semiconductor structure of clause 1, wherein the frontside metal wire is not vertically aligned with the backside metal wire and a horizontal distance between the frontside metal wire and the backside metal wire is less than a length of the deep trench via.

Clause 8: A method of forming a semiconductor structure, the method comprising forming a first sacrificial gate of a first nanosheet (NS) transistor, a second sacrificial gate of a second NS transistor, and a third sacrificial gate on a substrate; forming a first source/drain (S/D) region of the first NS transistor between the first sacrificial gate and the third sacrificial gate; forming a second S/D region of the second NS transistor between the second sacrificial gate and the third sacrificial gate; forming a backside contact in the substrate underneath a single diffusion break region; forming a deep trench via in the single diffusion break region directly above the backside contact, the single diffusion break region being between the first S/D region of the first NS transistor and the second S/D region of the second NS transistor; forming a frontside metal wire conductively connected to a top surface of the deep trench via; and forming a backside metal wire conductively connected to a bottom surface of the deep trench via.

Clause 9: The method of clause 8, further comprising forming a frontside via directly contacting the top surface of the deep trench via, wherein the frontside metal wire directly contacts the frontside via.

Clause 10: The method of clause 8, further comprising forming a backside via directly contacting the backside contact, wherein the backside metal wire directly contacts the backside via.

Clause 11: The method of clause 8, further comprising forming a first set of inner spacers between the first S/D region of the first NS transistor and a first side of the deep trench via; and forming a second set of inner spacers between the second S/D region of the second NS transistor and a second side of the deep trench via, wherein the first side of the deep trench via is opposite the second side of the deep trench via.

Clause 12: The method of clause 8, wherein forming the backside contact comprises selectively removing the third sacrificial gate and one or more nanosheets exposed by the removal of the third sacrificial gate to create a first opening between the first S/D region of the first NS transistor and the second S/D region of the second NS transistor, the first opening exposing the substrate; recessing a portion of the substrate to create a second opening in the substrate; and filling the second opening with a conductive material to form the backside contact.

Clause 13: The method of clause 12, wherein forming the deep trench via comprises filling the first opening between the first S/D region and the second S/D region, in the single diffusion region, with the conductive material to form the deep trench via.

Clause 14: The method of clause 8, wherein forming the frontside metal wire comprises forming the frontside metal wire in a first direction perpendicular to the deep trench via; and wherein forming the backside metal wire comprises forming the backside metal wire, from a backside of the substrate, in a second direction perpendicular to the deep trench via and parallel to the first direction, wherein the backside metal wire is not vertically aligned with the frontside metal wire.

Clause 15: The method of clause 8, further comprising forming a gate cut dielectric insulating a metal gate from the deep trench via, wherein the deep trench via is in a width direction of the metal gate.

Clause 16: A semiconductor structure comprising a first source/drain (S/D) region of a first nanosheet (NS) transistor and a second S/D region of a second NS transistor; a deep trench via in a single diffusion break region between the first S/D region and the second S/D region; a frontside metal wire conductively connected to a top surface of the deep trench via; and a backside metal wire conductively connected to a bottom surface of the deep trench via.

Clause 17: The semiconductor structure of clause 16, further comprising a metal gate and a gate cut dielectric, wherein the deep trench via is in a width direction of the metal gate and the gate cut dielectric insulates the metal gate from the deep trench via.

Clause 18: The semiconductor structure of clause 17, wherein the frontside metal wire is not vertically aligned with the backside metal wire and a horizontal distance between the frontside and backside metal wires is less than a length of the deep trench via, the length of the deep trench via is along the width direction of the metal gate.

Clause 19: The semiconductor structure of clause 16, further comprising a first set of inner spacers between the first S/D region and a first side of the deep trench via and a second set of inner spacers between the second S/D region and a second side of the deep trench via, the first side being opposite the second side.

Clause 20: The semiconductor structure of clause 16, further comprising a frontside via, a backside via, and a backside contact, wherein the frontside metal wire is conductively connected to the top surface of the deep trench via through the frontside via, and the backside metal wire is conductively connected to the bottom surface of the deep trench via through the backside via and the backside contact.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a deep trench via in a single diffusion break region;
a frontside metal wire conductively connected to a top surface of the deep trench via; and
a backside metal wire conductively connected to a bottom surface of the deep trench via,
wherein the frontside metal wire and the backside metal wire are parallel to each other and perpendicular to the deep trench via.

2. The semiconductor structure of claim 1, further comprising a metal gate and a gate cut dielectric, wherein the deep trench via is in a width direction of the metal gate and the gate cut dielectric separates the deep trench via from the metal gate.

3. The semiconductor structure of claim 1, further comprising a first set of inner spacers directly contacting a first side of the deep trench via and a second set of inner spacers directly contacting a second side of the deep trench via, the first side of the deep trench via being opposite the second side of the deep trench via.

4. The semiconductor structure of claim 3, further comprising a first source/drain (S/D) region of a first nanosheet (NS) transistor and a second S/D region of a second NS transistor, wherein the first S/D region directly contacts the first set of inner spacers and the second S/D region directly contacts the second set of inner spacers.

5. The semiconductor structure of claim 1, further comprising a frontside via, a backside via, and a backside contact, wherein the frontside metal wire is conductively connected to the top surface of the deep trench via through the frontside via, and the backside metal wire is conductively connected to the bottom surface of the deep trench via through the backside via and the backside contact.

6. The semiconductor structure of claim 5, wherein the backside contact is directly adjacent to a shallow-trench-insulation (STI), the STI being directly underneath the deep trench via and embedded in a substrate.

7. The semiconductor structure of claim 1, wherein the frontside metal wire is not vertically aligned with the backside metal wire and a horizontal distance between the frontside metal wire and the backside metal wire is less than a length of the deep trench via.

8. A method of forming a semiconductor structure, the method comprising:
forming a first sacrificial gate of a first nanosheet (NS) transistor, a second sacrificial gate of a second NS transistor, and a third sacrificial gate on a substrate;
forming a first source/drain (S/D) region of the first NS transistor between the first sacrificial gate and the third sacrificial gate;
forming a second S/D region of the second NS transistor between the second sacrificial gate and the third sacrificial gate;
forming a backside contact in the substrate underneath a single diffusion break region;
forming a deep trench via in the single diffusion break region directly above the backside contact, the single diffusion break region being between the first S/D region of the first NS transistor and the second S/D region of the second NS transistor;
forming a frontside metal wire conductively connected to a top surface of the deep trench via; and
forming a backside metal wire conductively connected to a bottom surface of the deep trench via.

9. The method of claim 8, further comprising forming a frontside via directly contacting the top surface of the deep trench via, wherein the frontside metal wire directly contacts the frontside via.

10. The method of claim 8, further comprising forming a backside via directly contacting the backside contact, wherein the backside metal wire directly contacts the backside via.

11. The method of claim 8, further comprising:
forming a first set of inner spacers between the first S/D region of the first NS transistor and a first side of the deep trench via; and
forming a second set of inner spacers between the second S/D region of the second NS transistor and a second side of the deep trench via,
wherein the first side of the deep trench via is opposite the second side of the deep trench via.

12. The method of claim 8, wherein forming the backside contact comprises:
selectively removing the third sacrificial gate and one or more nanosheets exposed by the removal of the third sacrificial gate to create a first opening between the first S/D region of the first NS transistor and the second S/D region of the second NS transistor, the first opening exposing the substrate;
recessing a portion of the substrate to create a second opening in the substrate; and
filling the second opening with a conductive material to form the backside contact.

13. The method of claim 12, wherein forming the deep trench via comprises filling the first opening between the first S/D region and the second S/D region, in the single diffusion region, with the conductive material to form the deep trench via.

14. The method of claim 8, wherein forming the frontside metal wire comprises forming the frontside metal wire in a first direction perpendicular to the deep trench via; and wherein forming the backside metal wire comprises forming the backside metal wire, from a backside of the substrate, in a second direction perpendicular to the deep trench via and parallel to the first direction, wherein the backside metal wire is not vertically aligned with the frontside metal wire.

15. The method of claim 8, further comprising forming a gate cut dielectric insulating a metal gate from the deep trench via, wherein the deep trench via is in a width direction of the metal gate.

16. A semiconductor structure comprising:
a first source/drain (S/D) region of a first nanosheet (NS) transistor and a second S/D region of a second NS transistor;
a deep trench via in a single diffusion break region between the first S/D region and the second S/D region;
a frontside metal wire conductively connected to a top surface of the deep trench via; and
a backside metal wire conductively connected to a bottom surface of the deep trench via.

17. The semiconductor structure of claim 16, further comprising a metal gate and a gate cut dielectric, wherein the deep trench via is in a width direction of the metal gate and the gate cut dielectric insulates the metal gate from the deep trench via.

18. The semiconductor structure of claim 17, wherein the frontside metal wire is not vertically aligned with the backside metal wire and a horizontal distance between the frontside and backside metal wires is less than a length of the deep trench via, the length of the deep trench via is along the width direction of the metal gate.

19. The semiconductor structure of claim 16, further comprising a first set of inner spacers between the first S/D region and a first side of the deep trench via and a second set of inner spacers between the second S/D region and a second side of the deep trench via, the first side being opposite the second side.

20. The semiconductor structure of claim 16, further comprising a frontside via, a backside via, and a backside contact, wherein the frontside metal wire is conductively connected to the top surface of the deep trench via through the frontside via, and the backside metal wire is conductively connected to the bottom surface of the deep trench via through the backside via and the backside contact.
